(19) United States
(12) Patent Application Publication
(10) Pub. No.: US 2026/0239572 A1
(43) Pub. Date: Aug. 13, 2026

(54) HEAT-CONDUCTIVE SHEET, HEAT-CONDUCTIVE SHEET LAMINATE, AND METHOD FOR PRODUCING HEAT-CONDUCTIVE SHEET

(71) Applicant: KANEKA CORPORATION, Osaka (JP)

(72) Inventors: Yasushi NISHIKAWA, Tokyo (JP); Takeshi NAKAGAKI, Tokyo (JP); Takahiro MORIKAWA, Mohka-shi (JP)

(73) Assignee: KANEKA CORPORATION, Osaka (JP)

(21) Appl. No.: 19/156,822

(22) PCT Filed: Feb. 15, 2024
(86) PCT No.: PCT/JP2024/005261

§ 371 Date: Aug. 14, 2025

(30) Foreign Application Priority Data
Feb. 16, 2023 (JP) 2023-022918

(51) Int. Cl. H05K 7/20; B32B 3/30; B32B 27/20

(52) U.S. Cl. CPC H05K 7/2039; B32B 3/30; B32B 27/20; B32B 2307/302; B32B 2307/7376

(57) ABSTRACT

An object is to provide a thermally conductive sheet that can be used in a narrower space and is less likely to corrode electronic components that come into contact with the thermally conductive sheet. The object is attained by a thermally conductive sheet that contains a composition containing graphite particles (A) and an organic polymer compound (B), the graphite particles (A) being oriented in a thickness direction of the thermally conductive sheet, the thermally conductive sheet having a thermal resistance of not more than 0.20° C./W, the thermally conductive sheet having a sulfur content of not more than 0.30% by weight with respect to a total weight of the thermally conductive sheet.

### TECHNICAL FIELD

The present invention relates to a thermally conductive sheet, a thermally conductive sheet laminate, and a method for producing a thermally conductive sheet.

### BACKGROUND ART

Conventionally, there is known a technique for suppressing temperature rise by attaching a heat dissipator to a heat generator such as an electronic component. When the heat dissipator is used, a sheet-like member having thermal conductivity (thermally conductive sheet) is used in order to efficiently transfer heat from the heat generator to the heat dissipator (see, for example, Patent Literatures 1 and 2).

### CITATION LIST

### Patent Literature

[Patent Literature 1]
Pamphlet of International Publication No. 2008/053843
[Patent Literature 2]
Japanese Patent Application Publication, Tokukai, No. 2021-119606

### SUMMARY OF INVENTION

### Technical Problem

However, in order to use the thermally conductive sheet in a narrower space, it is necessary to reduce the thickness of the thermally conductive sheet. Furthermore, conventional thermally conductive sheets have room for improvement in terms of providing a thermally conductive sheet that is less likely to corrode electronic components that come into contact with the thermally conductive sheet. Further, there is a problem that as the thickness of a thermally conductive sheet is reduced, the adhesion of the thermally conductive sheet to an adherend is deteriorated.

It is an object of an aspect of the present invention to provide a thermally conductive sheet that has a reduced thickness, has a low thermal resistance in a thickness direction, and is less likely to corrode electronic components that come into contact with the thermally conductive sheet. It is an object of another aspect of the present invention to provide a thermally conductive sheet that has a reduced thickness, has a low thermal resistance in a thickness direction, is less likely to corrode electronic components that come into contact with the thermally conductive sheet, and exhibits excellent adhesion to an adherend.

### Solution to Problem

In order to attain the object, a thermally conductive sheet in accordance with an embodiment of the present invention is a thermally conductive sheet that contains a composition containing graphite particles (A) and an organic polymer compound (B), the graphite particles (A) being oriented in a thickness direction of the thermally conductive sheet, the thermally conductive sheet having a thermal resistance of not more than 0.20° C./W, the thermally conductive sheet having a sulfur content of not more than 0.30% by weight with respect to a total weight of the thermally conductive sheet, the thermally conductive sheet having a thickness of not more than 500 μm.

In order to attain the object, a method in accordance with an embodiment of the present invention for producing a thermally conductive sheet includes: a primary sheet forming step of forming a composition containing graphite particles (A) and an organic polymer compound (B) into sheets to thereby obtain primary sheets in each of which the graphite particles (A) are oriented in a direction parallel to a surface of the each of the primary sheets, the graphite particles (A) having a sulfur content of not more than 1.0% by weight; a laminate forming step of laminating the primary sheets to thereby obtain a laminate of the primary sheets; and a slicing step of slicing the laminate of the primary sheets along a cross section of laminated layers of the laminate to thereby obtain the thermally conductive sheet.

### Advantageous Effects of Invention

An aspect of the present invention makes it possible to provide a thermally conductive sheet that has a reduced thickness, has a low thermal resistance in a thickness direction, and is less likely to corrode electronic components that come into contact with the thermally conductive sheet. Another aspect of the present invention makes it possible to provide a thermally conductive sheet that has a reduced thickness, has a low thermal resistance in a thickness direction, is less likely to corrode electronic components that come into contact with the thermally conductive sheet, and exhibits excellent adhesion to an adherend.

### DESCRIPTION OF EMBODIMENTS

The following description will discuss embodiments of the present invention. The present invention is not, however, limited to the embodiments below. The present invention is not limited to the configurations described below, but may be altered in various ways within the scope of the claims. The present invention also encompasses, in its technical scope, any embodiment or example derived by combining technical means disclosed in respective differing embodiments or Examples. Further, it is possible to form a new technical feature by combining technical means disclosed in the respective embodiments. All of the academic documents and the patent literatures cited in the present specification are incorporated herein by reference. Any numerical range expressed as “A to B” in the present specification means “not less than A and not more than B (i.e., a range from A to B which includes both A and B)” unless otherwise stated.

### [1. Thermally Conductive Sheet]

A thermally conductive sheet in accordance with an embodiment of the present invention is a thermally conductive sheet that contains a composition containing graphite particles (A) and an organic polymer compound (B), the graphite particles (A) being oriented in a thickness direction of the thermally conductive sheet, the thermally conductive sheet having a thermal resistance of not more than 0.20° C./W, the thermally conductive sheet having a sulfur content of not more than 0.30% by weight with respect to a total weight of the thermally conductive sheet, the thermally conductive sheet having a thickness of not more than 500 μm.

### [1-1. Composition Containing Graphite Particles (A) and Organic Polymer Compound (B)]

### (Graphite Particles (A))

The thermally conductive sheet in accordance with an embodiment of the present invention contains the composition containing the graphite particles (A) and the organic polymer compound (B). Since the graphite particles (A) are included in the thermally conductive sheet, the graphite particles (A) having thermal conductivity are dispersed in the thermally conductive sheet. This makes it possible to improve thermal conductivity of the thermally conductive sheet and to thereby reduce thermal resistance of the thermally conductive sheet.

The inventors of the present invention paid attention to the fact that conventional thermally conductive sheets can corrode electronic components that come into contact with the thermally conductive sheets. The inventors of the present invention then conducted study which, as one of objectives, aimed to provide a thermally conductive sheet that is less likely to corrode electronic components that come into contact with the thermally conductive sheet. In the study, the inventors of the present invention found that, when the inventors used graphite particles having a low sulfur content, it was possible to remarkably reduce corrosion of electronic components that came into contact with the thermally conductive sheet. The reason for this can be that sulfur contained as an impurity in the graphite particles leached out as an acid and corroded the electronic components that came into contact with the thermally conductive sheet.

In an embodiment of the present invention, a content of sulfur contained in the graphite particles (A) is not more than 1.0% by weight, more preferably not more than 0.7% by weight, and even more preferably not more than 0.5% by weight.

The graphite particles (A) may each have a spherical shape or a non-spherical shape. Non-spherical graphite particles (A) are easily oriented and therefore make it possible to improve thermal conductivity in a direction of orientation and to thereby reduce thermal resistance in the direction of orientation. From this viewpoint, it is preferable that the thermally conductive sheet contain non-spherical graphite particles (A). Note that only one type of graphite particles (A) may be used, or two or more types may be used in combination.

The shape of each of the non-spherical graphite particles (A) is not particularly limited, and may be, for example, a plate-like shape such as a scale-like shape or a thin plate-like shape; an elliptical spherical shape; a needle-like shape; a rod-like shape; a fibrous shape; or an irregular shape. In particular, the non-spherical graphite particles (A) each having a plate-like shape such as a scale-like shape or a thin plate-like shape are easily oriented and easily able to maintain contact between the particles. This makes it possible to further improve the thermal conductivity in the direction of orientation and to thereby further reduce the thermal resistance in the direction of orientation. From this viewpoint, it is more preferable that the non-spherical graphite particles (A) each have a plate-like shape such as a scale-like shape or a thin plate-like shape.

In the present specification, “spherical” refers to being in the shape of a true sphere or an elliptical sphere having an aspect ratio of 1.0 to 1.5, in other words, a true sphere having an aspect ratio of 1.0 or an elliptical sphere having an aspect ratio of more than 1.0 and not more than 1.5, and does not necessarily have to be in the shape of a true sphere. Note that the aspect ratio in a case where a graphite particle (A) has a “spherical” shape refers to a ratio represented as “major axis/minor axis”. Further, “non-spherical” refers to a shape other than the “spherical” shape, that is, a shape having an aspect ratio of more than 1.5. Note that “elliptical spherical shape” refers to an ellipsoidal shape obtained by rotating an ellipse, like a rugby ball.

An aspect ratio of a “non-spherical” graphite particle (A) refers to a ratio (maximum length/minimum length) of a maximum length of the graphite particle (A) to a minimum length of the graphite particle (A), and for example, is a ratio (maximum length/thickness) of a maximum length of the graphite particle (A) to a thickness of the graphite particle (A) in a case where the graphite particle (A) has a plate-like shape. The aspect ratio can be determined by: observing a sufficient number (e.g., not less than 10) of graphite particles (A) with use of a scanning electron microscope to calculate respective “major axis/minor axis” ratios of the graphite particles (A) or respective “maximum length/minimum length” ratios of the graphite particles (A); and calculating an average value of the ratios.

In a case where two or more types of graphite particles (A) are used, the aspect ratio is an average aspect ratio calculated as a weighted mean of the respective aspect ratios of the two or more types of graphite particles (A).

The aspect ratio of the graphite particles (A) is preferably not less than 20, more preferably not less than 40, and even more preferably not less than 70, from the viewpoint of improving the thermal conductivity in the direction of orientation. An upper limit of the aspect ratio is not particularly limited, and is ordinarily not more than 1000. In a case where the graphite particles (A) have an aspect ratio of not less than 20, causing the graphite particles (A) to be oriented in the thickness direction of the thermally conductive sheet makes it possible to further improve the thermal conductivity in the thickness direction of the thermally conductive sheet and to thereby further reduce the thermal resistance in the thickness direction of the thermally conductive sheet. It is therefore preferable that the aspect ratio of the graphite particles (A) be not less than 20.

Examples of the graphite particles (A) used in an embodiment of the present invention encompass particles of scale-like graphite, flake graphite, earthy graphite, artificial graphite, sliced graphite, acid-treated graphite, expanded graphite, carbon fiber flakes, and the like.

An average particle size of the graphite particles (A) is preferably 20 μm to 1000 μm, more preferably 30 μm to 500 μm, and particularly preferably 40 μm to 240 μm. The average particle size of the graphite particles (A) is a value determined with use of a laser diffraction/scatter particle size distribution meter (LA-920, manufactured by Horiba, Ltd.).

In a case where the average particle size of the graphite particles (A) is not less than 20 μm, the graphite particles (A) are oriented in a desired direction in the thermally conductive sheet so that a good heat transfer path is easily formed. Further, in a case where an upper limit of the average particle size of the graphite particles (A) is within the above range, the graphite particles are exposed on the surface of the heat conductive sheet. This makes it possible to enhance the heat transfer from the heat generator to the thermally conductive sheet when the thermally conductive sheet comes into contact with the heat generator.

In a case where the graphite particles (A) each have a plate-like shape, an average thickness of the graphite particles (A) is preferably 0.01 μm to 10 μm, more preferably 0.1 μm to 5 μm, and particularly preferably 0.3 μm to 3 μm. Note that the average thickness of the graphite particles (A) can be determined by: observing a sufficient number (e.g., not less than 10) of graphite particles (A) by electron microscopy with use of an ultra-high resolution scanning electron microscope (S-4800, manufactured by Hitachi, Ltd.) to calculate respective thicknesses of the graphite particles (A); and calculating an average value of the thicknesses.

In a case where a lower limit of the average thickness of the graphite particles (A) is within the above range, the amount of heat transport per particle is increased, and it is easier to form a good heat transfer path. Further, in a case where an upper limit of the average thickness of the graphite particles (A) is within the above range, the number of graphite particles (A) per unit weight increases, and the graphite particles (A) are oriented in a desired direction due to interference between the particles. This makes it easier to form a good heat transfer path.

### (Organic Polymer Compound (B))

The thermally conductive sheet in accordance with an embodiment of the present invention contains the composition containing the graphite particles (A) and the organic polymer compound (B). The organic polymer compound (B) not only functions as a binder but also improves the flexibility of the thermally conductive sheet to thereby allow a heat generator and a heat dissipator to be well adhered to each other via the thermally conductive sheet.

The organic polymer compound (B) is not particularly limited, and may be an organic polymer compound that is generally used in a thermally conductive sheet.

Examples of the organic polymer compound (B) include an acrylic ester-based resin, a resin (silicone resin) having repeating siloxane bonds as a main chain, a resin (elastomer resin) having rubber-like elasticity at room temperature, an epoxy resin, a fluororesin, a polyolefin, polyvinyl chloride, polyvinylidene chloride, polyvinyl acetate, an ethylene-vinyl acetate copolymer, polyvinyl alcohol, polyacetal, polyethylene terephthalate, polybutylene terephthalate, polyethylene naphthalate, polystyrene, polyacrylonitrile, a polyphenylene ether, a modified polyphenylene ether, aliphatic polyamides, aromatic polyamides, polyamide-imide, polycarbonate, polyphenylene sulfide, polysulfone, polyether sulfones, polyether nitrile, polyether ketone, polyketone, polyurethane, a liquid crystal polymer, and an ionomer. One type of these may be used alone, or two or more types may be used in combination.

The organic polymer compound (B) may be in a solid state or a liquid state at room temperature. In the present specification, “room temperature” refers to 20° C.

In particular, from the viewpoint of obtaining a thermally conductive sheet having excellent flexibility, the organic polymer compound (B) is more preferably one or more types selected from the group consisting of: an acrylic ester-based resin; a resin (silicone resin) having repeating siloxane bonds as a main chain; a fluororesin; and a resin (elastomer resin) having rubber-like elasticity at room temperature.

The acrylic ester-based resin encompasses: a polymer of monomer components including one or more types of acrylic monomers selected from the group consisting of (meth)acrylic acids and a (meth)acrylic esters; and a copolymer of the acrylic monomer(s) with another monomer(s). In the present specification, “(meth)acrylic” is intended to include both of “methacrylic” and “acrylic”. Examples of the (meth)acrylic ester include methyl (meth)acrylate, ethyl (meth)acrylate, n-butyl (meth)acrylate, isobutyl (meth)acrylate, 2-ethylhexyl (meth)acrylate, and cyclohexyl (meth)acrylate. Examples of the acrylic monomer(s) also include an acrylic monomer having a functional group such as a OH group or a COOH group. By using an acrylic ester-based resin in which an acrylic monomer having these functional groups is used as a part of the monomers, it is possible to more firmly fix the graphite. Note that these functional groups may be included in the another monomer(s) (described below).

Examples of the another monomer(s) include acrylonitrile, glycidyl methacrylate, and 2-chloroethyl vinyl ether. Note that by copolymerizing a (meth)acrylic ester with acrylonitrile, 2-chloroethyl vinyl ether, and the like, acrylic rubber is obtained. Acrylic rubber is also classified as an elastomer resin, which will be described later, but in the present specification, acrylic rubber is considered to be encompassed in an acrylic ester-based resin.

A more preferable example of the acrylic ester-based resin is an acrylic ester-based resin that contains either or both of butyl acrylate and 2-ethylhexyl acrylate as a monomer(s) in a total amount of not less than 50% by weight with respect to a total amount of the monomer components. The acrylic ester-based resin is preferable for making it easy to achieve a high flexibility, having excellent chemical stability and processability, and making it easy to control adhesiveness. Further, it is preferable, in terms of long-term adhesion retention and film strength, that the acrylic ester-based resin includes a crosslinked structure to the extent that flexibility is not impaired. The inclusion of the crosslinked structure can be achieved, for example, by reacting a polymer having a —OH group with a compound having an isocyanate group. Alternatively, the inclusion of the crosslinked structure can be achieved, for example, by reacting a polymer having a —COOH group with a compound having an epoxy group.

The use of the acrylic ester-based resin provides the advantage of making it possible to obtain a thermally conductive sheet that has adhesiveness and elasticity such that the thickness of the thermally conductive sheet can be restored. The acrylic ester-based polymer may be used alone or in combination of two or more types.

A weight average molecular weight of the acrylic ester-based polymer is preferably 100,000 to 2,000,000, more preferably 250,000 to 1,500,000, and even more preferably 400,000 to 1,300,000. A weight-average molecular weight of not less than 100,000 tends to provide excellent film strength, and a weight-average molecular weight of not more than 2,000,000 tends to provide excellent flexibility. Note that the weight-average molecular weight can be measured by gel permeation chromatography with use of a calibration curve of standard polystyrene.

A glass transition temperature (Tg) of the acrylic ester-based polymer is preferably not higher than 20° C., more preferably −70° C. to 0° C., and even more preferably −50° C. to −20° C. A glass transition temperature of not higher than 20° C. tends to provide excellent flexibility and adhesiveness. Note that the glass transition temperature (Tg) can be calculated from tan δ derived from measurement of dynamic viscoelastic behaviors.

Examples of the resin (silicone resin) having repeating siloxane bonds as a main chain include silicone oil, silicone grease, silicone rubber, and a silicone resin having a three-dimensional network structure (a silicon resin in a narrow sense). Silicone rubber is also classified as an elastomer resin, which will be described later, but in the present specification, silicone rubber is considered to be encompassed in the resin having repeating siloxane bonds as a main chain.

The silicone resin may also be in a solid state or a liquid state at room temperature. From the viewpoint of increasing the flexibility of the thermally conductive sheet, it is also preferable that liquid silicone such as silicone oil be contained.

Only one type of silicone resin may be used, or two or more types may be used in combination.

Examples of the resin (elastomer resin) having rubber-like elasticity at room temperature include acrylonitrile butadiene rubber, hydrogenated acrylonitrile butadiene rubber, ethylene-propylene rubber, natural rubber, isoprene rubber, chloroprene rubber, butyl rubber, butadiene rubber, hydrogenated butadiene rubber, styrene-butadiene rubber, and hydrogenated styrene-butadiene rubber. As described above, in the present specification, elastomer resin refers to elastomer resins other than acrylic rubber and silicone rubber. Only one type of elastomer resin may be used, or two or more types may be used in combination.

Examples of the fluororesin include, but are not limited to, a vinylidene fluoride/hexafluoropropylene copolymer, a vinylidene fluoride-hexafluoropentene-tetrafluoroethylene terpolymer, a perfluoropropene oxide polymer, and a tetrafluoroethylene-propylene-vinylidene fluoride copolymer.

In an embodiment of the present invention, a total amount of the acrylic ester-based resin, the silicone resin, the fluororesin, and the elastomer resin in the organic polymer compound (B) is preferably not less than 60% by weight, more preferably not less than 80% by weight, even more preferably not less than 90% by weight, and most preferably 100% by weight.

### (Composition)

In an embodiment of the present invention, the composition containing the graphite particles (A) and the organic polymer compound (B) only needs to contain the graphite particles (A) and the organic polymer compound (B), but may contain an additive(s) such as a flame retardant, an antioxidant, a heat stabilizer, a coloring agent, an antistatic agent, and a filler other than the graphite particles (A), as necessary. Note that in a production process of the thermally conductive sheet, the graphite particles (A), the organic polymer compound (B), and the additive(s) may be mixed with a solvent to form a primary sheet, and in the present specification, “composition” refers to a composition after the solvent is removed by drying or the like, that is, a composition contained in the ultimately obtained electrically conductive sheet.

The flame retardant is not particularly limited, but for example, a phosphorus-based flame retardant such as a red phosphorus-based flame retardant and a phosphoric ester-based flame retardant can be suitably used.

Examples of the red phosphorus-based flame retardant include red phosphorus. It is also preferable to use red phosphorus that has been coated with various coatings for the purpose of enhancing safety and stability.

Examples of the phosphoric ester-based flame retardant include trimethyl phosphate, triethyl phosphate, tributyl phosphate, triphenyl phosphate, tricresyl phosphate, cresyl diphenyl phosphate, trixylenyl phosphate, xylenyl diphenyl phosphate, cresyl-2,6-xylenyl phosphate, tris(t-butylated phenyl)phosphate, tris(isopropylated phenyl)phosphate, triaryl phosphate isopropylated, resorcinol bisdiphenyl phosphate, bisphenol A bis(diphenyl phosphate), and resorcinol bisdixylenyl phosphate. One type of these may be used alone, or two or more types may be used in combination. Among them, it is more preferable that the phosphate ester-based flame retardant include a phosphoric ester-based flame retardant that is in a liquid state at room temperature. The phosphoric ester-based flame retardant that is in a liquid state at room temperature is preferable due to reducing the hardness of the thermally conductive sheet and therefore increasing the adhesion of the thermally conductive sheet to a semiconductor and a spreader.

In an embodiment of the present invention, a content of the graphite particles (A) in the composition is preferably 30% by weight to 80% by weight, more preferably 35% by weight to 75% by weight, and even more preferably 40% by weight to 70% by weight, with respect to a total weight of the composition. The content of the graphite particles (A) of not less than 30% by weight is preferable due to allowing sufficient thermal conductivity to be exhibited. The content of the graphite particles (A) of not more than 80% by weight is preferable due to allowing excellent flexibility and adhesion to be exhibited.

In an embodiment of the present invention, the content of the organic polymer compound (B) in the composition is preferably 10% by weight to 60% by weight, more preferably 15% by weight to 50% by weight, and even more preferably 20% by weight to 40% by weight, with respect to the total weight of the composition. The content of the organic polymer compound (B) of not less than 10% by weight is preferable due to improving the flexibility of the thermally conductive sheet and therefore causing a heat generator and a heat dissipator to be well adhered to each other via the thermally conductive sheet. Further, the higher the content of the organic polymer compound (B) is within the range of not more than 60% by weight, the better the graphite particles (A) can be fixed, and the higher the adhesion with a semiconductor and a spreader. It is therefore preferable that the content of the organic polymer compound (B) be as high as possible within the range of not more than 60% by weight.

In an embodiment of the present invention, the content of the flame retardant is not particularly limited but is preferably 1% by weight to 60% by weight, more preferably 5% by weight to 50% by weight, and even more preferably 10% by weight to 40% by weight, with respect to the total weight of the composition. The content of the flame retardant of not less than 1% by weight is preferable due to allowing sufficient flame retardancy to be exhibited. In a case where the content of the flame retardant is not more than 60% by weight, the strength of the thermally conductive sheet is less likely to decrease. Further, the content of phosphoric ester-based flame retardant of not more than 60% by weight is preferable due to reducing the hardness of the thermally conductive sheet and therefore increasing the adhesion of the thermally conductive sheet to a semiconductor and a spreader.

A ratio of the content of the organic polymer compound (B) to the content of the flame retardant (content of the organic polymer compound (B)/content of the flame retardant) is preferably 0.5 to 2.0, more preferably 0.7 to 1.6, and even more preferably 0.8 to 1.4. The ratio within the above range is preferable due to allowing sufficient flame retardancy to be exhibited.

### [1-2. Thermally Conductive Sheet]

The thermally conductive sheet in accordance with an embodiment of the present invention is a thermally conductive sheet in which the graphite particles (A) are oriented in the thickness direction of the thermally conductive sheet, the thermally conductive sheet having a thermal resistance of not more than 0.20° C./W, the thermally conductive sheet having a sulfur content of not more than 0.30% by weight with respect to the total weight of the thermally conductive sheet, the thermally conductive sheet having a thickness of not more than 500 μm.

### (Orientation of Graphite Particles (A))

The graphite particles (A) are oriented in the thickness direction of the thermally conductive sheet. The graphite particles (A) being oriented in the thickness direction of the thermally conductive sheet is preferable because of making it possible to improve the thermal conductivity in the thickness direction in which the graphite particles (A) are oriented, and consequently to reduce the thermal resistance in the thickness direction in which the graphite particles (A) are oriented. Note that, as long as the thermal conductivity can be improved in the thickness direction of the orientation, it is not necessary for all of the graphite particles (A) contained in the thermally conductive sheet to be oriented in the thickness direction of the thermally conductive sheet.

That the graphite particles (A) are oriented in the thickness direction of the thermal conductive sheet means that an angle of a plane of a six-membered carbon ring in a crystal of each graphite particle (A) with respect to a sheet surface of the thermally conductive sheet is more than 45°. The angle is more preferably not less than 50°, even more preferably not less than 70°, and particularly preferably not less than 80°. Note that the angle of a plane of a six-membered carbon ring with respect to the sheet surface of the thermally conductive sheet refers to the smaller one of the two angles formed by the plane and the sheet surface, except in a case where the two angles are each 90°. Note that in the graphite particles (A), the plane of a six-membered carbon ring in a crystal of each graphite particle (A) is oriented in a direction of a plane of a scale or a thin plate in a case where the graphite particle (A) has a plate-like shape such as a scale-like or thin plate-like shape, and oriented in a long axis direction of the graphite particle in a case where the graphite particle (A) has an elliptical spherical, needle-like, rod-like, fibrous, or irregular shape. Note that a long axis of the graphite particle (A) is in the same direction as the maximum length of the graphite particle (A).

The angle of the plane of a six-membered carbon ring in a crystal of each graphite particle (A) with respect to the sheet surface, which is a surface of the thermally conductive sheet, can be measured by observing a cross section of the thermally conductive sheet in a thickness direction of the thermally conductive sheet with use of a scanning electron microscope. First, a thin film slice is prepared from a center part of the thermally conductive sheet in the thickness direction. Then, graphite particles (A) in the thin film slice are observed with use of a scanning electron microscope, and angles between long axes of any 20 graphite particles (A) and the sheet surface are measured. This allows determining the angle of the plane of a six-membered carbon ring in a crystal of each graphite particle (A) with respect to the sheet surface. In the present specification, the angle of not less than 45°, the angle of not less than 50°, the angle of not less than 70°, and the angle of not less than 80° described above each mean that an average value of the values measured as described above is not less than that angle. Note that in a case where an angle between a long axis of a graphite particle (A) and the sheet surface exceeds 90°, a supplementary angle thereof is taken as a measured value.

(Physical Properties Etc. Of Thermally Conductive Sheet)

The thermal resistance of the thermally conductive sheet in accordance with an embodiment of the present invention is preferably not more than 0.20° C./W, more preferably not more than 0.12° C./W, even more preferably not more than 0.10° C./W, and particularly preferably not more than 0.08° C./W. Note that in the present specification, a thermal resistance is thermal conduction in the thickness direction of the thermally conductive sheet, and is a thermal resistance value measured by a method described in Examples. In a case where the thermal resistance is not more than 0.20° C./W, the thermally conductive sheet has excellent thermal conductivity and excellent heat dissipation characteristics when interposed between a heat generator and a heat dissipator to form a heat dissipation device. The lower the thermal resistance, the better.

The thickness of the thermally conductive sheet in accordance with an embodiment of the present invention is preferably not more than 500 μm, more preferably not more than 200 μm, even more preferably not more than 140 μm, still even more preferably 100 μm, still even more preferably not more than 95 μm, and particularly preferably not more than 80 μm. Note that in the present specification, the thickness of the thermally conductive sheet is a thickness measured by a method described in Examples. The thickness of the thermally conductive sheet of not more than 500 μm is preferable because of allowing the thermally conductive sheet to be attached to a heat generator such as an electronic component even in a narrow space. A lower limit of the thickness of the thermally conductive sheet is not particularly limited as long as the thermally conductive sheet functions as a thermally conductive sheet, but is preferably not less than 3 μm, and more preferably not less than 5 μm.

A sulfur content of the thermally conductive sheet in accordance with an embodiment of the present invention is preferably not more than 0.30% by weight, more preferably not more than 0.25% by weight, even more preferably not more than 0.20% by weight, and particularly preferably not more than 0.10% by weight, with respect to the total weight of the thermally conductive sheet. Note that in the present specification, the sulfur content of the thermally conductive sheet is a sulfur content measured by a method described in Examples. The sulfur content of the thermally conductive sheet of not more than 0.30% by weight is preferable because of making it less likely for an electronic component that come into contact with the thermally conductive sheet to be corroded. The lower the sulfur content of the thermally conductive sheet, the better. A lower limit of the sulfur content of the thermally conductive sheet is not particularly limited but is, for example, not less than 0.01% by weight.

A hardness of the thermally conductive sheet in accordance with an embodiment of the present invention at 20° C. is preferably not less than 65, more preferably not less than 70, even more preferably not less than 75, and particularly preferably not less than 80. Note that in the present specification, the hardness of the thermally conductive sheet at 20° C. is a hardness measured by a method described in Examples. The hardness of the thermally conductive sheet of not less than 65 at 20° C. is preferable because of allowing the thermally conductive sheet to be sufficiently hard and therefore be sliced into thin thicknesses. Further, the hardness of the thermally conductive sheet at 20° C. is preferably not more than 95, more preferably not more than 90, and even more preferably not more than 88. In a case where the hardness of the thermally conductive sheet at 20° C. is not more than 95, the thermally conductive sheet can be sufficiently adhered to components with which the thermally conductive sheet comes into contact. This allows heat to be transferred well, so that thermal stress can be sufficiently relieved.

A hardness of the thermally conductive sheet in accordance with an embodiment of the present invention at 70° C. is preferably more than 60, more preferably not less than 63, and even more preferably not less than 65. Note that in the present specification, the hardness of the thermally conductive sheet at 70° C. is a hardness measured by a method described in Examples. The hardness of the thermally conductive sheet of more than 60 at 70° C. is preferable because of allowing the thermally conductive sheet to be sufficiently hard and therefore be sliced into thin thicknesses. Further, the hardness of the thermally conductive sheet at 70° C. is preferably not more than 90, more preferably not more than 85, and even more preferably not more than 83. In a case where the hardness of the thermally conductive sheet at 70° C. is not more than 90, the thermally conductive sheet can be sufficiently adhered to components with which the thermally conductive sheet comes into contact. This allows heat to be transferred well, so that thermal stress can be sufficiently relieved.

The thermally conductive sheet in accordance with an embodiment of the present invention has stripe-shaped recesses formed on a surface of the thermally conductive sheet. That is, in the present embodiment, the surface of the thermally conductive sheet has a projection-and-recess structure, in which the recesses are formed in a stripe-like shape. The recesses only need to be formed in a stripe-like shape, and are formed, for example, in a substantially linear shape. The plurality of stripe-shaped recesses do not intersect with each other, and are more preferably formed substantially parallel to each other. Note that the formation of stripe-shaped recesses on the surface of the thermally conductive sheet can be confirmed by visual observation based on a difference in color between the recesses and the other parts, by touch, and/or by measurement with use of, for example, a roughness meter.

In an embodiment of a production method described below, in a thermally conductive sheet manufactured by a method including a primary sheet forming step, a laminate forming step, and a slicing step, the stripe-shaped recesses are formed parallel to a surface of a primary sheet that appears on the surface of the thermally conductive sheet. The reason why the stripe-shaped recesses are formed is unclear but is speculated to be a difference in physical properties between an inside of each primary sheet and a laminate interface in the laminate forming step of laminating primary sheets to obtain a laminate of the primary sheets. Note that the present invention is not limited to such speculation. For example, the stripe-shaped recesses are formed in a portion corresponding to the laminate interface. Further, the stripe-shaped recesses tend to be formed in a case where the primary sheets are formed by coating (solvent casting) in the primary sheet forming step. The stripe-shaped recesses tend not to be formed in a case where the primary sheets are formed by rolling, pressing, or extrusion.

A depth of each of the recesses from the other parts, i.e., a height difference between each recess and the other parts, is not particularly limited as long as the recess is lower than the other parts. For example, the depth is 40 μm to 1 μm. An interval between adjacent recesses is also not particularly limited.

In a case where a thermally conductive sheet has a certain degree of thickness, the thermally conductive sheet is pressed against the adherend and therefore adheres to the adherend easily. As the thickness of a thermally conductive sheet decreases, however, a problem arises that the adhesion of the thermally conductive sheet to an adherend is deteriorated. With the thermally conductive sheet in accordance with the present embodiment, the presence of a projection-and-recess structure on the surface of the thermally conductive sheet allows air to be discharged through the recesses, so that air entrapment is prevented. Further, since the resin component is contained in a large amount at the recesses, good conformability is achieved when the thermally conductive sheet is caused to adhere to an adherend. As such, the thermally conductive sheet in accordance with the present embodiment, which has a projection-and-recess structure on the surface thereof, has the advantage of excellent adhesion to the adherend, even in a case where the thermally conductive sheet is reduced in thickness.

Further, due to the formation of the stripe-shaped recesses, a surface roughness of the thermally conductive sheet in a direction perpendicular to the stripes is greater than that in a direction parallel to the stripes. A surface roughness Ra of the surface of the thermally conductive sheet in the direction perpendicular to the stripes is preferably 1 μm to 7 μm, more preferably 2 μm to 6 μm. A surface roughness Rz of the surface of the thermally conductive sheet in the direction perpendicular to the stripes is preferably 5 μm to 35 μm, more preferably 10 μm to 30 μm. A surface roughness Ra of the surface of the thermally conductive sheet in the direction parallel to the stripes is preferably 0.5 μm to 3 μm, more preferably 0.8 μm to 2.5 μm. A surface roughness Rz of the surface of the thermally conductive sheet in the direction parallel to the stripes is preferably 5 μm to 20 μm, more preferably 7 μm to 15 μm. Note that the surface roughnesses of the surface of the thermally conductive sheet in the directions perpendicular and parallel to the stripes are values measured by the method described in Examples.

On the surface of the thermally conductive sheet, a ratio of a surface roughness in a direction perpendicular to the stripes to a surface roughness in a direction parallel to the stripes (a surface roughness in the direction perpendicular to the stripes on the surface of the thermally conductive sheet/a surface roughness in the direction parallel to the stripes on the surface of the thermally conductive sheet) is preferably not less than 1.3 and not more than 15, and more preferably not less than 1.5. The ratio within the above range is preferable because of allowing the thermally conductive sheet to have excellent adhesion to an adherend even in a case where the thickness of the thermally conductive sheet is small. Note that “a surface roughness in the direction perpendicular to the stripes on the surface of the thermally conductive sheet/a surface roughness in the direction parallel to the stripes on the surface of the thermally conductive sheet” is, in other words, “a surface roughness in a lamination direction of the primary sheets/a surface roughness in a direction perpendicular to the lamination direction of the primary sheets”.

### [2. Method for Producing Thermally Conductive Sheet]

A method in accordance with an embodiment of the present invention for producing a thermally conductive sheet is not particularly limited, provided that the method is capable of producing the thermally conductive sheet described above. For example, the method includes: a primary sheet forming step of forming a composition containing graphite particles (A) and an organic polymer compound (B) into sheets to thereby obtain primary sheets in each of which the graphite particles (A) are oriented in a direction parallel to a surface of the each of the primary sheets, the graphite particles (A) having a sulfur content of not more than 1.0% by weight; a laminate forming step of laminating the primary sheets to thereby obtain a laminate of the primary sheets; and a slicing step of slicing the laminate of the primary sheets along a cross section of laminated layers of the laminate to thereby obtain the thermally conductive sheet.

### (Primary Sheet Forming Step)

In the primary sheet forming step, the composition containing the graphite particles (A) and the organic polymer compound (B) is formed into sheets to thereby obtain primary sheets in each of which the graphite particles (A) are oriented in a direction parallel to a surface of the each of the primary sheets, the graphite particles (A) having a sulfur content of not more than 1.0% by weight.

Note that the graphite particles (A) having a sulfur content of not more than 1.0% by weight, the organic polymer compound (B), and the composition containing the graphite particles (A) and the organic polymer compound (B) are as described above in [1-1.].

Examples of the method for forming the composition into sheets to thereby obtain primary sheets in each of which the graphite particles (A) are oriented in the direction parallel to the surface of each of the primary sheets include a method in which the graphite particles (A), the organic polymer compound (B), and, as necessary, the above-described additive(s) are mixed with or without addition of a solvent, and a resultant mixture is formed into sheets to thereby prepare primary sheets in each of which the graphite particles (A) are oriented in a direction substantially parallel to a main surface.

Examples of the solvent include: an aromatic hydrocarbon solvent such as toluene or xylene; an ester-based solvent such as ethyl acetate or butyl acetate; a ketone-based solvent such as methyl ethyl ketone or methyl isobutyl ketone (MIBK); and a cellosolve-based solvent such as butyl cellosolve, phenyl cellosolve, or dimethyl cellosolve. An amount of the solvent is preferably such that a total concentration of the graphite particles (A), the organic polymer compound (B), and the additive(s) is 10% by weight to 50% by weight, and more preferably 20% by weight to 40% by weight. It is preferable to prepare the primary sheets with this concentration because in that case, there is an appropriate amount of space between the graphite particles, so that good particle orientation is achieved at the time of sheet preparation and lamination and pressing.

A method for mixing the graphite particles (A), the organic polymer compound (B), and, as necessary, the additive(s) described above, with or without addition of a solvent is not particularly limited. Examples of the method include a method in which the organic polymer compound (B) is dissolved in a solvent, and the graphite particles (A) and, as necessary, other additive(s) are added thereto and mixed. The mixing method is also not particularly limited, and mixing by stirring, roll kneading, mixing with use of a kneader, mixing with use of a Brabender, mixing with use of an extruder, and the like can be employed.

A method for subsequently forming the obtained mixture into sheets is not particularly limited, and for example, the mixture can be subjected to rolling, pressing, extrusion, or coating to prepare primary sheets in each of which the graphite particles (A) are oriented in a direction substantially parallel to the main surface. In a case where a solvent is used at the time of mixing, the added solvent may be removed by drying or the like before or after the mixture is formed into sheets.

When the composition is formed into sheets, a thickness of each of the sheets is preferably at least 20 times an average value of the maximum lengths of the graphite particles (A) or an average value of major axes of the graphite particles (A), and more preferably 20 times to 100 times the average value of the maximum lengths or the average value of the major axes. The thickness within the above range is preferable because of allowing a sheet with high strength to be obtained.

### (Laminate Forming Step)

The laminate forming step is a step of laminating the primary sheets to obtain a laminate of the primary sheets. A method for laminating the primary sheets is not particularly limited, and examples of the method include a method of laminating a plurality of primary sheets and a method of folding a primary sheet. When laminating the primary sheets, it is preferable to laminate the primary sheets such that a direction in which the graphite particles (A) are oriented within the sheet plane is the same among the primary sheets.

Pressure that is applied when the primary sheets are laminated is not particularly limited, but is adjusted so as to be low enough to prevent a sliced surface from being crushed out of shape in the subsequent slicing step but high enough to ensure good bonding between the primary sheets. The lamination may be performed under heating as appropriate.

The pressure applied when the primary sheets are laminated may be applied each time a primary sheet is placed on top, each time a plurality of primary sheets are stacked, or after all the primary sheets are stacked. A preferable example can be a method in which (i) pressure is applied each time a primary sheet is placed on top or each time a plurality of primary sheets are stacked and (ii) pressure is also applied after all the primary sheets are stacked. In this case, the pressure applied each time a primary sheet is placed on top or each time a plurality of primary sheets are stacked and a temperature at which the pressure is applied are not particularly limited, but for example, the pressure is 1 kgf/cm² to 100 kgf/cm² and the temperature is 20° C. to 200° C. Further, the pressure applied after all the primary sheets are stacked and a temperature at which the pressure is applied are not particularly limited either, but for example, the pressure is 1 kgf/cm² to 100 kgf/cm² and the temperature is 20° C. to 200° C.

### (Slicing Step)

In the slicing step, the laminate of the primary sheets is sliced along a cross section of laminated layers of the laminate to thereby obtain a thermally conductive sheet. An angle at which the laminate of the primary sheets is sliced along the cross section of the laminated layers is not particularly limited, but it is preferable that the laminate of the primary sheets be sliced along a cross section of the laminated layers at an angle of not more than 45°, more preferably at an angle of 0° to 30°, and particularly preferably at an angle of 0° to 15° to a lamination direction to obtain a thermally conductive sheet. By slicing the laminate at an angle of not more than 45° with respect to the lamination direction, a thermally conductive sheet having excellent thermal conductivity can be obtained.

A method for slicing the laminate of the primary sheets is not particularly limited, and examples of the method include a multi-blade method, a laser processing method, a water jet method, and a knife processing method.

An aspect of the present invention also includes a thermally conductive sheet obtained by the above production method.

### [3. Thermally Conductive Sheet Laminate]

An aspect of the present invention also includes a thermally conductive sheet laminate that includes: the thermally conductive sheet; and a protection film that covers one surface or both surfaces of the thermally conductive sheet. With this configuration, for example, in a case where the thermally conductive sheet has adhesiveness, the adhesive surface can be protected.

A material of the protective film is not particularly limited, and may be, for example, (i) a resin film of polyethylene, polypropylene, polyester, polyethylene terephthalate, polyimide, polyetherimide, polyether naphthalate, methylpentene, or the like, (ii) a paper film of fine paper, coated paper, craft paper, recycled paper, or the like, or (iii) a metal foil of aluminum or the like. The protective film may be a single-layer film made of any one selected from the films and the metal foil described above, or a multilayer film in which two or more types selected from the films and the metal foil described above are laminated.

The protective film is peelable from the thermally conductive sheet. The protective film may be provided in direct contact with the thermally conductive sheet, or may be provided with another layer such as a release layer interposed therebetween. Examples of the release layer include a layer containing a silicone-based, silica-based, or other release agent, and the like.

In a case where both surfaces of the thermally conductive sheet are covered with the protective film, a front surface and a back surface of the thermally conductive sheet may be covered with respective protective films that differ in peel strength. This is preferable due to providing excellent workability, because it is possible to first peel off the protective film having the weaker peel strength from one of the surfaces and apply the thermally conductive sheet to the substrate, so that the protective film on the other surface is prevented from falling off.

It is also preferable to apply an insulating protective film to one or both surfaces of the thermally conductive sheet, because this allows the thermally conductive sheet to be used in areas where electrical insulation is required.

The thermally conductive sheet laminate in accordance with an embodiment of the present invention may further include an insulating film in addition to the protective film. In such a case, it is preferable for the protective film to be the outermost layer from the viewpoint of protecting the thermally conductive sheet.

A thickness of the protective film is not particularly limited, but is, for example, 10 μm to 300 μm, more preferably 50 μm to 150 μm, and even more preferably 50 μm to 100 μm.

A size of the protective film is not particularly limited as long as the size is large enough to cover the thermally conductive sheet, and may be the same as or larger than a size of the thermally conductive sheet.

In an embodiment of the present invention, at least one protection film selected from the group consisting of: the protection film that covers one surface of the thermally conductive sheet; and the protection film that covers both surfaces of the thermally conductive sheet may be a film having a size large enough for a plurality of cut pieces of the thermally conductive sheet to be arranged on the film.

The cut pieces of the thermally conductive sheet may have a shape and a size that are appropriately selected in accordance with a shape(s) and a size(s) of the heat generator, the heat dissipator, and/or the like each serving as an adherend. Examples of a shape of a main surface of each of the cut pieces of the thermally conductive sheet include: a quadrilateral shape such as a rectangular shape or a square shape; a polygonal shape such as a hexagonal shape; a circular shape; and an elliptic shape. The size of each of the cut pieces of the thermally conductive sheet may be such that, in a case where, for example, the main surface is quadrilateral, each of the cut pieces is 3 mm to 100 mm in length on one side, and may be 5 mm to 80 mm in length on one side.

Further, the number of the plurality of cut pieces of the thermally conductive sheet that are arranged on at least one protection film selected from the group consisting of: the protection film that covers one surface of the thermally conductive sheet; and the protection film that covers both surfaces of the thermally conductive sheet is not particularly limited, as long as the number is not less than two. For example, the number may be 2 to 50. A shape of the film on which the plurality of cut pieces of the thermally conductive sheet are arranged is not particularly limited, and may be, for example, a quadrangular shape such as a rectangular shape or a square shape, a long shape, or the like. In a case where the film has a long shape, the thermally conductive sheet laminate may be provided in a roll shape by winding the film in a state in which the plurality of cut pieces of the thermally conductive sheets are arranged on the film. This allows the thermally conductive sheet arranged on the long film to be conveyed together with the long film and mounted on the adherend.

A size of the film on which the plurality of cut pieces of the thermally conductive sheet are arranged is not particularly limited, provided that the size is large enough for a desired number of cut pieces of the thermally conductive sheet to be arranged on the film.

The plurality of cut pieces of the thermally conductive sheet may be arranged on the film with no gaps between the plurality of cut pieces, or may be arranged on the film with gaps between the plurality of cut pieces.

Aspects of the present invention can also be expressed as follows.

Embodiments of the present invention include the following.

<1> A thermally conductive sheet, containing a composition containing graphite particles (A) and an organic polymer compound (B), the graphite particles (A) being oriented in a thickness direction of the thermally conductive sheet, the thermally conductive sheet having a thermal resistance of not more than 0.20° C./W, the thermally conductive sheet having a sulfur content of not more than 0.30% by weight with respect to a total weight of the thermally conductive sheet, the thermally conductive sheet having a thickness of not more than 500 μm.

<2> The thermally conductive sheet described in <1>, wherein stripe-shaped recesses are formed on a surface of the thermally conductive sheet.

<3> The thermally conductive sheet described in <2>, wherein a ratio of a surface roughness Ra in a direction perpendicular to stripes of the stripe-shaped recesses to a surface roughness Ra in a direction parallel to the stripes (a surface roughness in the direction perpendicular to the stripes on the surface of the thermally conductive sheet/a surface roughness in the direction parallel to the stripes on the surface of the thermally conductive sheet) is not less than 1.3.

<4> The thermally conductive sheet described in any one of <1> to <3>, wherein the thermally conductive sheet has a thermal resistance of not more than 0.10° C./W.

<5> The thermally conductive sheet described in any one of <1> to <4>, wherein the thermally conductive sheet has a sulfur content of not more than 0.10% by weight with respect to the total weight of the thermally conductive sheet.

<6> The thermally conductive sheet described in any one of <1> to <5>, wherein the thermally conductive sheet has a thickness of not more than 140 μm.

<7> The thermally conductive sheet described in any one of <1> to <6>, wherein the thermally conductive sheet has a thickness of not more than 100 μm.

<8> The thermally conductive sheet described in any one of <1> to <7>, wherein a content of the graphite particles (A) is 30% by weight to 80% by weight with respect to a total weight of the composition.

<9> A thermally conductive sheet laminate, including: a thermally conductive sheet described in any one of <1> to <8>; and a protection film that covers one surface or both surfaces of the thermally conductive sheet.

<10> The thermally conductive sheet laminate described in <9>, wherein a plurality of cut pieces of the thermally conductive sheet are arranged on at least one protection film selected from the group consisting of: the protection film that covers one surface of the thermally conductive sheet; and the protection film that covers both surfaces of the thermally conductive sheet.

<11> A method for producing a thermally conductive sheet, the method including: a primary sheet forming step of forming a composition containing graphite particles (A) and an organic polymer compound (B) into sheets to thereby obtain primary sheets in each of which the graphite particles (A) are oriented in a direction parallel to a surface of the each of the primary sheets, the graphite particles (A) having a sulfur content of not more than 1.0% by weight; a laminate forming step of laminating the primary sheets to thereby obtain a laminate of the primary sheets; and a slicing step of slicing the laminate of the primary sheets along a cross section of laminated layers of the laminate to thereby obtain the thermally conductive sheet.

<12> The method described in <11>, wherein the primary sheet forming step is a step of forming the primary sheets by coating.

<13> A thermally conductive sheet obtained by a method described in <11> or <12>.

### EXAMPLES

The following description will discuss an embodiment of the present invention in more detail with reference to Examples and Comparative Examples. Note that the present invention is not limited to these examples.

### [Evaluation Method]

The following description will discuss evaluation methods in Examples and Comparative Examples.

### <Thermal Resistance Value>

A thermally conductive sheet was cut into a 1 cm×1 cm square to prepare a sample for evaluation. The sample for evaluation was subjected to measurement of a thermal resistance value (° C./W) of the thermally conductive sheet at a sample temperature of 50° C. and a pressure of 0.5 MPa with use of a thermal resistance measuring device (a device for measuring a thermal resistance of a resin material, manufactured by Hitachi Technologies and Services, Ltd.).

The thermal resistance of the thermally conductive sheet was evaluated according to the following criteria.
A (excellent): not more than 0.10° C./W
B (good): more than 0.10° C./W and not more than 0.30° C./W
C (poor): more than 0.30° C./W

### <Hardness>

A thermally conductive sheet was cut into a 3 cm×3 cm square to prepare a sample for evaluation. The sample for evaluation was subjected to measurement of hardness with use of a durometer (ASKER CL-150LJ, manufactured by Kobunshi Keiki Co., Ltd.) in conformity with the Asker C method of the standards (SRIS) of the Society of Rubber Science and Technology, Japan. A hardness at 20° C. was measured with temperature adjustment such that a temperature of the sample for evaluation measured by a surface thermometer was 20° C., and a hardness at 70° C. was measured with heating such that a temperature of the sample for evaluation measured by the surface thermometer was 70° C.

The hardness of the thermally conductive sheet at 20° C. was evaluated according to the following criteria.
A (excellent): not less than 80
B (good): not less than 65 and less than 80
C (poor): less than 65

The hardness of the thermally conductive sheet at 70° C. was evaluated according to the following criteria.
A (excellent): more than 60
C (poor): not more than 60

### <Thickness>

A thermally conductive sheet was cut into a 3 cm×3 cm square to prepare a sample for evaluation. Thicknesses at four corners and a center of the sample for evaluation were measured with use of a micrometer manufactured by Mitutoyo Corporation, and an average value of the measured values thus obtained was considered to be a thickness of the thermally conductive sheet. Note here that the “center” indicates a position of an intersection of (i) a line via which two of the four corners, which two are diagonally located, are connected and (ii) a line via which the other two of the four corners, which two are diagonally located, are connected.

### <Sulfur Content>

A sulfur content (% by weight) of a thermally conductive sheet was determined by elemental analysis with use of a scanning X-ray fluorescence analyzer (ZSX Primus III+, manufactured by Rigaku Corporation).

The sulfur content of the thermally conductive sheet was evaluated according to the following criteria.
A (excellent): not more than 0.10% by weight
B (good): more than 0.10% by weight and not more than 0.30% by weight
C (poor): more than 0.30% by weight

### <Surface Roughness in Direction Perpendicular to Stripes on Surface of Thermally Conductive Sheet (Surface Roughness in Lamination Direction of Primary Sheets)>

Surface roughness was measured in conformity with JIS B 0601. Specifically, with use of a surface roughness measuring instrument SJ-210 (code No. 178-2560-11) (manufactured by Mitutoyo Corporation), a surface roughness Ra and a surface roughness Rz of a thermally conductive sheet, which had been cut into a size of 10 mm long×10 mm wide, in a direction perpendicular to the stripes of stripe-shaped recesses (in a lamination direction of primary sheets, in a case where no stripe-shaped recesses were formed) were each measured. Note that the above measurement was carried out three times per surface of the sheet, i.e., a total of six measurements for both surfaces, with a reference length (L) of 4 mm, and an average value of the six measurements was taken as the surface roughness.

### <Surface Roughness in Direction Parallel to Stripes on Surface of Thermally Conductive Sheet (Surface Roughness Perpendicular to Lamination Direction of Primary Sheets)>

A surface roughness Ra and a surface roughness Rz in a direction parallel to the stripes were measured in the same manner as the surface roughnesses in the direction perpendicular to the stripes described above, except that the measurement direction was changed from the direction perpendicular to the stripes to the direction parallel to the stripes.

### Example 1

### (Preparation of Composition)

120 g of scale-like graphite powder (average particle size: 73 μm, thickness: 0.80 μm, aspect ratio: 91, sulfur content: not more than 1.0% by weight) as the graphite particles (A), 266.6 g of an acrylic ester-based resin (weight average molecular weight: 1,200,000, Tg: −37° C., containing a OH group as a functional group, 15% by weight of a toluene/ethyl acetate solution) (40 g as an acrylic ester-based resin) as the organic polymer compound (B), 40 g of cresyl di(2,6-xylenyl)phosphate as a flame retardant, and 226.6 g of methyl ethyl ketone were stirred and mixed for 10 minutes with use of a planetary centrifugal mixer to obtain a stirred mixture.

### <Formation of Primary Sheets>

The obtained stirred mixture was spread on a polytetrafluoroethylene (PTFE) sheet and dried at 120° C. for not less than 20 minutes, and then a formed sheet was peeled off to obtain a primary sheet having a thickness of 2 mm. This operation was repeated to prepare a large number of primary sheets.

A content of the graphite particles (A) was 60% by weight, a content of the organic polymer compound (B) was 20% by weight, and a content of the flame retardant was 20% by weight, with respect to a total weight of the composition contained in the primary sheets obtained by drying the stirred mixture (the composition contained in the ultimately obtained thermally conductive sheets).

### <Formation of Laminate>

Each of the obtained large number of primary sheets was cut into a 2.5 cm×5 cm piece, and these pieces were stacked such that every time another piece was placed on top, the stack was pressed at room temperature with a pressure of not less than 100 kg (8 kgf/cm²). The placing and pressing was repeated until the stack ultimately had a thickness of not less than 5 cm after pressing. Subsequently, the stack obtained by stacking the primary sheets until the thickness was not less than 5 cm was pressed at 150° C. with a pressure of not less than 1 t (80 kgf/cm²) to obtain a laminate of 5 cm×5 cm×5 cm.

### <Production of Thermally Conductive Sheet>

The obtained laminate was sliced along a cross section of laminated layers of the laminate at an angle of 0 degrees to a lamination direction (in other words, the laminate was sliced in a direction normal to main surfaces of the laminated primary sheets). Thus obtained was a thermally conductive sheet which was 5 cm in length, 5 cm in width, and 75 μm in thickness and in which the graphite particles were oriented in a thickness direction.

### Examples 2 to 4

A thermally conductive sheet was prepared in the same manner as in Example 1, except that the amounts of the scale-like graphite powder, the acrylic ester-based resin, and the cresyl di(2,6-xylenyl)phosphate contained were changed to the amounts indicated in Table 1.

### Comparative Example 1

12 g of scale-like expanded graphite powder (average particle size: 250 μm, thickness 5 μm, aspect ratio: 50, sulfur content: not less than 1.5% by weight) as the graphite particles (A), 40 g of an acrylic ester-based resin (the same resin as the acrylic ester-based resin used in Example 1, 15% by weight of a toluene/ethyl acetate solution) (6 g as the acrylic ester-based resin) as the organic polymer compound (B), and 8 g of cresyl di(2,6-xylenyl)phosphate were stirred well with use of a stainless steel spoon to obtain a stirred mixture. The obtained stirred mixture was spread on a PET (polyethylene terephthalate) film which had been treated to have a releasing property, was air-dried in a draft at room temperature for 3 hours, and then was dried in a hot air dryer at 120° C. for 1 hour to obtain a composition. With respect to a total weight of the composition obtained by drying the stirred mixture, a content of the graphite particles (A) was 46% by weight, a content of the organic polymer compound (B) was 23% by weight, and a content of the flame retardant was 31% by weight.

### <Formation of Primary Sheets>

1 g of the obtained composition was rolled into a block of 6 mm in height, sandwiched between PET films which had been treated to have a releasing property, and pressed for 20 seconds with use of a press having a tool surface of 5 cm×10 cm under conditions of a tool pressure of 10 MPa and a tool temperature of 170° C. to obtain a primary sheet of 0.3 mm in thickness. This operation was repeated to prepare a large number of primary sheets.

### <Formation of Laminate>

The obtained primary sheets were each cut into a 2 cm×2 cm sheet, and 37 sheets thus cut were stacked such that the graphite particles were oriented in the same direction. The sheets were lightly pressed by hand to be bonded together, so that a laminate of 1.1 cm in thickness was obtained.

### <Production of Thermally Conductive Sheet>

The obtained laminate was cooled to −15° C. with use of dry ice and then sliced along a 1.1 cm×2 cm cross section of laminated layers at an angle of 0 degrees to the lamination direction. Thus obtained was a thermally conductive sheet of 1.1 cm in length, 2 cm in width, and 0.58 mm in thickness.

### Comparative Example 2

### (Preparation of Composition)

40 parts by weight of a thermoplastic fluororesin that is solid at room temperature and normal pressure (manufactured by Daikin Industries, Ltd., product name: “DAI-EL G-704BP”) and 45 parts by weight of a thermoplastic fluororesin that is liquid at room temperature and normal pressure (manufactured by Daikin Industries, Ltd., product name: “DAI-EL G-101”) as the organic polymer compound (B), 85 parts by weight of expanded graphite (manufactured by Ito Graphite Co., Ltd., product name: “EC-50”, volume average particle size: 250 μm, thickness: 5 μm, aspect ratio: 50, sulfur content: not less than 1.5% by weight) as the graphite particles (A), 0.1 parts by weight of a readily dispersible aggregate of fibrous carbon nanostructures, and 5 parts by weight of a sebacic acid ester (manufactured by Daihachi Chemical Industry Co., Ltd., product name: “DOS”) as a plasticizer were mixed by stirring for 5 minutes at room temperature with use of a mixer in the presence of 100 parts of ethyl acetate as a solvent. Then, the resulting stirred mixture was subjected to defoaming under vacuum for 30 minutes, and the ethyl acetate was removed at the same time as the defoaming. Thus obtained was a composition containing: graphite particles; an organic polymer compound; and a readily dispersible aggregate of carbon nanostructures and a plasticizer, which were additives.

A content of the graphite particles (A) was 48.5% by weight, a content of the organic polymer compound (B) was 48.5% by weight, and a content of the flame retardant was 3% by weight, with respect to a total weight of the composition (the composition contained in the ultimately obtained thermally conductive sheets) contained in the primary sheets obtained by drying the stirred mixture.

### <Formation of Primary Sheets>

5 g of the obtained composition was sandwiched between PET films and rolled with a gap of 550 μm between rolls and a roll temperature of 50° C. to obtain a primary sheet having a thickness of 0.5 mm.

### <Formation of Laminate>

The obtained primary sheet was cut into a 6 cm×6 cm piece (thickness: 0.5 mm) and such pieces were laminated in a thickness direction of the primary sheet to obtain a laminate having a thickness of approximately 6 cm.

### <Production of Thermally Conductive Sheet>

The obtained laminate was sliced along a cross section of laminated layers of the laminate at an angle of 0 degrees to a lamination direction (in other words, the laminate was sliced in a direction normal to main surfaces of the laminated primary sheets). Thus obtained was a sheet of 6 cm in length, 6 cm in width, and 0.5 mm in thickness. Subsequently, the obtained sheet was pressed for 30 seconds with use of a hot press machine with press plates heated to 50° C. and a pressure of 2.6 MPa to obtain a thermally conductive sheet of 6 cm in length, 6 cm in width, and 125 μm in thickness.

### [Evaluation of Thermally Conductive Sheets]

The thermally conductive sheets obtained in Examples 1 to 4 and Comparative Examples 1 and 2 were each subjected to measurement of a thermal resistance, a hardness, a thickness, and a sulfur content. Further, the thermally conductive sheets were each observed as to the presence or absence of stripe-shaped recesses on a surface thereof, and a surface roughness in a direction perpendicular to the stripes (or a surface roughness in the lamination direction of the primary sheets, in a case where there were no stripe-shaped recesses) and a surface roughness in a direction perpendicular to the stripes (or a surface roughness in a direction perpendicular to the lamination direction of the primary sheets, in a case where there were no stripe-shaped recesses) on the surface of the thermally conductive sheet were measured. A ratio of these surface roughnesses Ra was calculated. The measurement results and evaluation, the presence or absence of stripe-shaped recesses on the surface, and the ratio of the surface roughnesses Ra are shown in Table 1.

TABLE 1

| | | | | | Comp. | Comp. |
|---|---|---|---|---|---|---|
| | Example 1 | Example 2 | Example 3 | Example 4 | Example 1 | Example 2 |
| Content of graphite particles (A) with respect to | 60 | 60 | 50 | 50 | 46 | 48.5 |
| total weight of composition | | | | | | |
| (% by weight) | | | | | | |
| Content of organic polymer compound (B) | 20 | 16 | 25 | 20 | 23 | 48.5 |
| with respect to total weight of composition | | | | | | |
| (% by weight) | | | | | | |
| Content of additive(s) with respect to | 20 | 24 | 25 | 30 | 31 | 3 |
| total weight of composition | | | | | | |
| (% by weight) | | | | | | |
| Thermal resistance (° C./W) | A | A | A | A | C | B |
| | 0.07 | 0.07 | 0.07 | 0.07 | >0.21 | 0.14 |
| Hardness at 20° C. | A | A | B | B | C | B |
| Hardness at 70° C. | A | A | A | A | C | C |
| Thickness (μm) | 75 | 75 | 95 | 95 | 580 | 125 |
| Sulfur content (% by weight) | A | A | A | A | C | C |
| | 0.085 | 0.085 | 0.080 | 0.080 | 0.35 | 0.38 |
| Presence or absence of stripe-shaped recesses on surface | Present | Present | Present | Present | Absent | Absent |
| Ratio of surface roughnesses Ra | ≥1.5 | ≥1.5 | ≥1.5 | ≥1.5 | <1.3 | <1.3 |

Further, it was confirmed that in the cases where the thermally conductive sheets obtained in Examples 1 to 4, each of which had a sulfur content of not more than 1.0% by weight, were used, electronic components that came into contact with the thermally conductive sheets were less likely to corrode compared to the cases in which the thermally conductive sheets obtained in Comparative Examples 1 and 2, each of which had a sulfur content of more than 3.0% by weight, were used.

### INDUSTRIAL APPLICABILITY

An embodiment of the present invention makes it possible to provide a thermally conductive sheet that has a reduced thickness, has a low thermal resistance in a thickness direction, and is less likely to corrode electronic components that come into contact with the thermally conductive sheet.

This is extremely useful because it is possible to provide a thermally conductive sheet that can be attached, even in a narrow space, to a heat generator such as an electronic component, that has a high thermal conductivity, and that is less likely to corrode the electronic component.

1. A thermally conductive sheet comprising:
a composition including graphite particles and an organic polymer compound,
the graphite particles being oriented in a thickness direction of the thermally conductive sheet,
the thermally conductive sheet having a thermal resistance of not more than 0.20° C./W,
the thermally conductive sheet having a sulfur content of not more than 0.30% by weight with respect to a total weight of the thermally conductive sheet, and
the thermally conductive sheet having a thickness of not more than 500 μm.

2. The thermally conductive sheet as set forth in claim 1, wherein
the thermally conductive sheet having a surface including stripe-shaped recesses.

3. The thermally conductive sheet as set forth in claim 2, wherein
a ratio of a surface roughness Ra in the direction perpendicular to the stripe-shaped recesses on the surface of the thermally conductive sheet to a surface roughness Ra in the direction parallel to the stripe-shaped recesses on the surface of the thermally conductive sheet is not less than 1.3.

4. The thermally conductive sheet as set forth in claim 1, wherein
the thermally conductive sheet has a thermal resistance of not more than 0.10° C./W.

5. The thermally conductive sheet as set forth in claim 1, wherein
the thermally conductive sheet has a sulfur content of not more than 0.10% by weight with respect to the total weight of the thermally conductive sheet.

6. The thermally conductive sheet as set forth in claim 1, wherein
the thermally conductive sheet has a thickness of not more than 140 μm.

7. The thermally conductive sheet as set forth in claim 1, wherein
the thermally conductive sheet has a thickness of not more than 100 μm.

8. The thermally conductive sheet as set forth in claim 1, wherein
a content of the graphite particles is 30% by weight to 80% by weight with respect to a total weight of the composition.

9. A thermally conductive sheet laminate, comprising:
a thermally conductive sheet recited in claim 1; and
a protection film that covers one surface or both surfaces of the thermally conductive sheet.

10. The thermally conductive sheet laminate as set forth in claim 9, wherein
a plurality of cut pieces of the thermally conductive sheet are arranged on at least one protection film selected from the group consisting of: the protection film that covers one surface of the thermally conductive sheet; and the protection film that covers both surfaces of the thermally conductive sheet.

11. A method for producing a thermally conductive sheet, the method comprising:
forming a composition containing graphite particles and an organic polymer compound into sheets to thereby obtain primary sheets in each of which the graphite particles are oriented in a direction parallel to a surface of the each of the primary sheets, the graphite particles having a sulfur content of not more than 1.0% by weight;
laminating the primary sheets to obtain a laminate of the primary sheets; and
slicing the laminate of the primary sheets along a cross section of laminated layers of the laminate to obtain the thermally conductive sheet.

12. The method as set forth in claim 11, wherein
the forming of the primary sheets includes forming the primary sheets by coating.

13. A thermally conductive sheet obtained by a method recited in claim 11.

14. The thermally conductive sheet as set forth in claim 2, wherein
the thermally conductive sheet has a thermal resistance of not more than 0.10° C./W.

15. The thermally conductive sheet as set forth in claim 2, wherein
the thermally conductive sheet has a sulfur content of not more than 0.10% by weight with respect to the total weight of the thermally conductive sheet.

16. The thermally conductive sheet as set forth in claim 2, wherein
the thermally conductive sheet has a thickness of not more than 140 μm.

17. The thermally conductive sheet as set forth in claim 2, wherein
the thermally conductive sheet has a thickness of not more than 100 μm.

18. The thermally conductive sheet as set forth in claim 2, wherein
a content of the graphite particles is 30% by weight to 80% by weight with respect to a total weight of the composition.

19. A thermally conductive sheet laminate, comprising:
a thermally conductive sheet recited in claim 2; and
a protection film that covers one surface or both surfaces of the thermally conductive sheet.

20. A thermally conductive sheet obtained by a method recited in claim 12.
